(19) United States
(12) Patent Application Publication
(10) Pub. No.: US 2002/0195351 A1
(43) Pub. Date: Dec. 26, 2002

(54) Copper electroplating composition for integrated circuit interconnection

(75) Inventors: Chih-Sheng Lu, Hsinchu (TW); Lu-Ming Luo, Hsinchu (TW); Yaw-Nan Shieh, Hsinchu (TW); Ray-Jaung Ho, Hsinchu (TW)

Correspondence Address: EDWARDS & ANGELL, LLP, 101 Federal Street,, Boston, MA, 02110, US

(73) Assignee: Chang Chun Plastics Co., Ltd.

(21) Appl. No.: 10/121,786

(22) Filed: Apr. 12, 2002

(30) Foreign Application Priority Data
Apr. 12, 2001 (TW) 90108728

(51) Int. Cl. C09D 5/00; C23C 16/00; C23C 20/00

(52) U.S. Cl. 205/574; 205/585; 106/1.23

(57) ABSTRACT

A copper electroplating composition for integrated circuit interconnection is proposed, including a copper salt, an inorganic acid containing same anion as the copper salt, a suppressing agent and a polishing agent. This electroplating composition helps deposit copper into fine trenches with a high aspect ratio on a substrate, so as to form a surface-flat and void-free plated copper layer over the substrate by electroplating. It can therefore reduce the usage of polishing slurry and polishing time in a subsequent chemical mechanical polishing process, and also improve surface planarity of the copper later after being polished.

### FIELD OF THE INVENTION

The present invention relates to copper electroplating compositions for integrated circuit interconnection, and more particularly, to a copper electroplating composition for helping deposit copper into fine trenches with a high aspect ratio on a substrate, so as to form a surface-flat and void-free plated copper layer over the substrate by electroplating, which copper layer can then be subjected to subsequent processes for fabricating integrated circuit interconnection.

### BACKGROUND OF THE INVENTION

Generally, a conventional process for fabricating copper-made integrated circuit interconnection comprises two steps: copper deposition and chemical mechanical polishing. Methods for copper deposition include physical vapor deposition, chemical vapor deposition, electroplating deposition and electroless deposition. In particular, the widely-used physical vapor deposition, as shown in FIG. 1, is firstly to deposit a barrier layer 2 onto a substrate 1, which barrier layer 2 can be made of tantalum or tantalum nitride. Then, a copper seed layer 3 is disposed over the barrier layer 2, and subsequently electroplated thereon with a copper layer for use as interconnection. Finally, in response to multi-layer interconnection structure, after electroplating, a chemical mechanical polishing step is carried out for grinding a surface of the copper layer to be flat and smooth, whereby fabrication of next-level interconnection can be proceeded thereon.

Typically, integrated circuit interconnection is composed of a plurality of interconnects with variable width ranging from 0.1 μm to several micrometers. During electroplating, an accelerator is usually adopted to achieve satisfactory trench filling for interconnection. However, this often causes over-filling and surface bulges to relatively fine trenches, or surface indentation to wider trenches. Therefore, in order to adapt the surface-indented trenches to be properly ground, normally electroplating time is increased to make a much thicker plated copper layer over the substrate 1, whereby redundant part of the copper layer can be ground off in a subsequent chemical mechanical polishing process, so as to provide a suitably flat and smooth surface for use in fabrication of next-level interconnection. However, such a scheme is disadvantageous in time-consuming and more usage in quantity of polishing slurry, thereby making capital costs undesirably increased.

During evolution of copper electroplating technology, it is always critical to form a fairly flat and even surface of a plated copper layer, as discussed in U.S. Pat. Nos. 6,110,346, 6,001,235 and 6,132,587. Such a copper layer is preferably required due to much finer trenches and narrower width of interconnects made for integrated circuits as compared to those for printed circuit boards.

A current issue is focused on how to enhance trench-filling ability for integrated circuit interconnection. For example, U.S. Pat. No. 6,024,857 discloses the addition of commercially-available Selrex Cubath M-HY 70/30 into soluble polymer with high molecular weight of 200,000 to 1,000,000, so as to help inhibit undesirably copper deposition outside the trenches for interconnection, and to allow complete filling of the trenches. Moreover, U.S. Pat. No 6,113,771 suggests to use a solution containing high concentration of copper ions along with low concentration of sulfuric acid, and including additives, e.g. organic bi-sulphide as a polishing agent, nitrogenous compounds as a smoothing agent, and oxygen-containing polymer as a suppressing agent. The high copper ion concentration helps accelerate diffusion of copper ions into the trenches for interconnection, thereby making the trench-filling ability desirably increased. Furthermore, Taiwanese Patent No 362270 proposes to utilize polyether compounds, organic sulfide and organic nitride as additives, allowing the trenches for interconnection to be filled in a bottom-up manner.

In addition, besides improving the trench-fill ability for making interconnection, surface planarity of the filled trenches also needs to be assured, as disclosed in U.S. Pat. Nos. 6,063,306 and 6,126,853, wherein the use of a suppressing agent is suggested for preventing over-polishing of a plated copper layer, so as to maintain certain surface flatness of the copper layer. Moreover, a normal strategy for achieving satisfactory surface planarity is to prolong polishing time; however, it is defective of using a larger amount of polishing slurry and increasing capital costs. In response, the basic solution is to plate a substantial flat surface of the copper layer during electroplating.

In respect of additives being used in electroplating, due to considerably small width of trenches for interconnection, normally additives with strong bottom-up filling ability are preferably selected. Integrated circuit interconnection consists of a plurality of variable-width interconnects, as shown in the FIG. 1. Therefore, referring to FIG. 2, during electroplating in the presence of additives, copper can be quickly deposited in a bottom-up manner at relatively narrower trenches 4; whereas the bottom-up filling ability of additives for copper deposition is worse in wider trenches 5, and worst in even larger trenches 6 where step coverage and surface indentation may occur. By virtue of diffusion and exchange action of the additives, as shown in FIG. 3, it usually results in surface bulges 7 at small trenches due to copper over-deposition; however, for larger trenches, reduced bottom-up filling action leads to flat surfaces or indented surfaces 8, which surface indentation is often overcome by increasing electroplating time to deposit more copper thereon for achieving suitable surfaces used in subsequent polishing proceeding,

### SUMMARY OF THE INVENTION

A primary objective of the present invention is to provide a copper electroplating composition for integrated circuit interconnection, allowing to form a flat surface of a plated copper layer by electroplating prior to performing a surface polishing process.

In accordance with the foregoing and other objectives, the present invention proposes a copper electroplating composition for integrated circuit interconnection, comprising a copper salt, an inorganic acid containing same anion as the copper salt, a compound containing nitrogen and sulphurous, oxygen-containing polymer and chloride ions; wherein electroplating is performed at current density of 0.5 to 5 ASD and with copper serving as anode, so as to form a surface-flat and void-free plated copper layer. This copper electroplating composition is characterized with simple content of additives used in an electroplating process, and allows to achieve a plated copper layer with satisfactory surface flatness during electroplating, so that polishing time and polishing slurry can both be reduced in usage during a chemical mechanical polishing process, with surface planarity of fabricated interconnection after polishing being desirably improved.

### BRIEF DESCRIPTION OF THE DRAWINGS

For a more complete understanding of the present invention, reference will now be made to the following detailed description of preferred embodiments taken in conjunction with the accompanying drawings, in which:

FIG. 1 (PRIOR ART) is a cross-sectional view showing a substrate with variable-width trenches to be subjected to a conventional electroplating process;

FIG. 2 (PRIOR ART) is a cross-sectional view showing a substrate with variable-width trenches during electroplating;

FIG. 3 (PRIOR ART) is a cross-sectional view showing a substrate with variable-width trenches after electroplating is completed;

FIG. 4 is a cross-sectional view showing a substrate with variable-width trenches thereon being electroplated to form a flat surface by using an electroplating composition of the invention;

FIG. 5 is a photo showing a cross-sectional view of a chip having a plurality of trenches being electroplated with copper by using an electroplating composition of the invention, wherein line width is 0.4 μm, trench diameter is 0.3 μm, and magnification is 9500 times;

FIG. 6 is a photo showing a cross-sectional view of a chip having a plurality of trenches being electroplated with copper by using an electroplating composition of the invention, wherein line width is 0.4 μm, trench diameter is 0.3 μm, and magnification is 27000 times;

FIG. 7 is a photo showing a cross-sectional view of a chip having a plurality of trenches being electroplated with copper by using an electroplating composition of the invention, wherein line width is 2.75 μm and magnification is 30000 times; and

FIG. 8 is a photo showing a cross-sectional view of a chip having a plurality of trenches being electroplated with copper by using an electroplating composition of the invention, wherein line width is 7.5 μm, trench diameter is 0.4 μm, an aspect ratio is 1.5, and magnification is 13000 times.

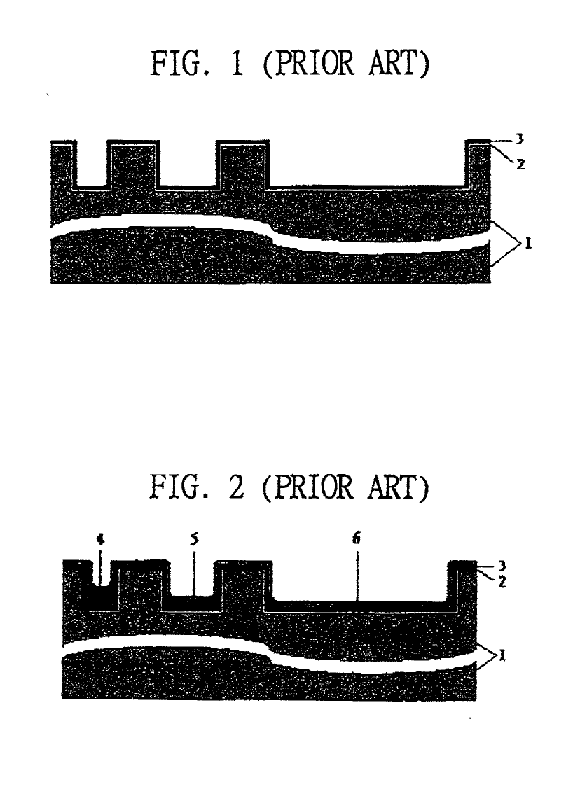

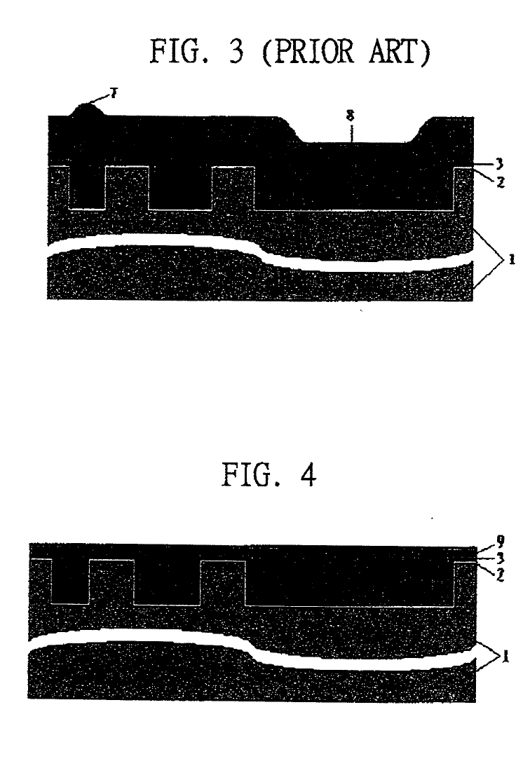

### DETAILED DESCRIPTION OF THE PREFERRED EMBODIMENT

Referring to FIG. 4, the present invention provides a copper electroplating composition for integrated circuit interconnection, and is characterized in forming a flat surface of a plated copper layer by electroplating, which therefore facilitates the proceeding of a subsequent polishing process, allowing polishing time and polishing slurry to be both reduced in usage.

The copper electroplating composition for integrated circuit interconnection of the invention, comprises a copper salt, an inorganic acid containing same anion as the copper salt, a compound containing nitrogen and sulphurous, oxygen-containing polymer and chloride ions; wherein electroplating is performed at current density of 0.5 to 5 ASD and with copper serving as anode, so as to form a surface-flat and void-free plated copper layer 9 shown in FIG. 4, wherein line width used in the interconnection is smaller than 10 μm, and an aspect ratio used in the interconnection is from 0.05 to 10.

The copper salt is selected from a group consisting of copper sulfate, copper phosphate and copper nitrate, and preferably copper sulfate. Content of copper sulfate ranges from 16 to 160 g/L.

The inorganic acid is selected from a group consisting of sulfuric acid, phosphoric acid and nitric acid, and preferably sulfuric acid. Content of sulfuric acid ranges from 18 to 200 g/L.

The compound containing nitrogen and sulphurous is a sulphurous-containing amino acid compound, which sulphurous-containing amino acid compound is selected from a group consisting of cysteine, percysteine, glutathione, and subsituents and salts thereof. Content of the sulphurous-containing amino acid compound ranges from 5 to 50 parts per million.

The oxygen-containing polymer includes polyethanediol, polypropanediol, and copolymer of ethanediol and propanediol. Content of the oxygen-containing polymer ranges from 100 to 1000 parts per million.

In addition, content of the chloride ions ranges from 1 to 100 parts per million, whereas the anode includes pure copper and phosphorous-containing copper.

In this invention, the compound containing nitrogen and sulphurous is used as a polishing agent, and the oxygen-containing polymer acts as a suppressing agent. Since electroplating is carried out in an acidic environment, the compound containing nitrogen and sulphurous would gain a proton and become a positively charged compound. During electroplating, this positively charged compound serves as a current suppressing agent, allowing more positively charged polishing agents to be attracted to trenches at positions with most concentrated current density. This makes copper deposition rate reduced at the concentrated-current positions without causing mouth-sealing effect, so as to form a flat plated layer during electroplating. Further, the chloride ions contained in the composition electroplating composition are used as a co-suppressor, whose content is relatively low without undesirably affecting quality and flatness of the electroplated copper layer.

Preferred Embodiments

### EXAMPLE 1

Take a chip routed with trenches as cathode and pure copper as anode; prepare a power supply of EG & G Potentiostat/Galvanostat model 263A. An electroplating composition is constituted as follows:

| | | |
|---|---|---|
| copper ion: | 17 | g/L |
| sulfuric acid: | 180 | g/L |
| chloride ion: | 3 | ppm |
| cysteine: | 20 | ppm |
| polyethanediol | 200 | ppm |
| (molecular weight = 6000): | | |

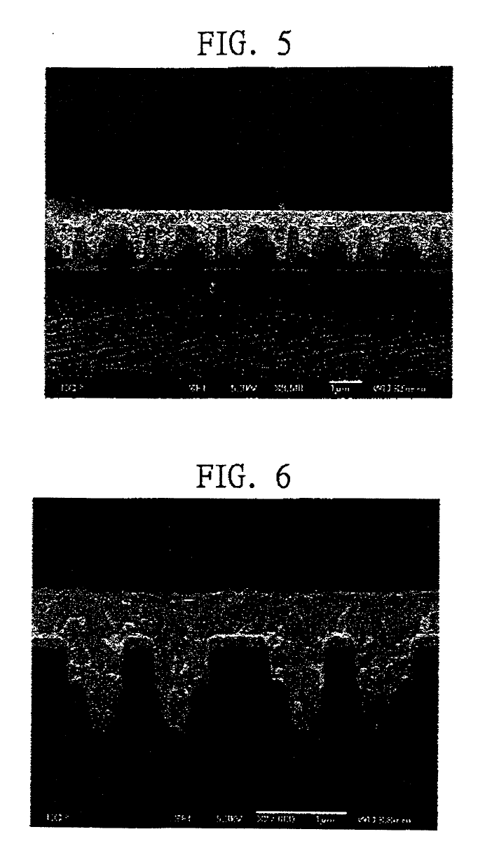

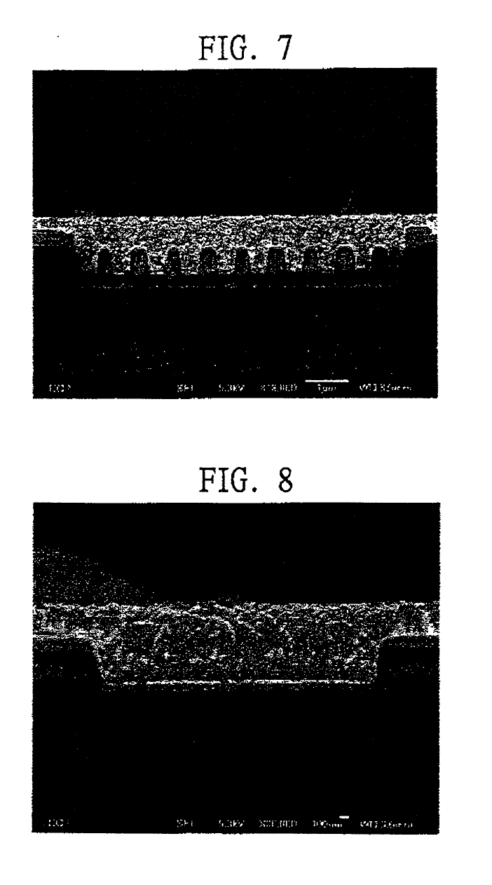

Perform an electroplating process by using the foregoing chip and pure copper as electrodes as mentioned above, with plating time being set for 90 seconds at current density of 2 ASD. Results are shown in FIGS. 5, 6, 7 and 8, wherein a surface-flat and void-free plated copper later is obtained respectively for all trenches with various line widths of 0.25 μm, 0.45 μm, 2.7 μm and 7.5 μm.

### EXAMPLE 2

Take a chip routed with trenches as cathode and pure copper as anode; prepare a power supply of EG & G Potentiostat/Galvanostat model 263A. An electroplating composition is constituted as follows:

| | | |
|---|---|---|
| copper ion: | 17 | g/L |
| sulfuric acid: | 180 | g/L |
| chloride ion: | 30 | ppm |
| cysteine: | 20 | ppm |
| polyethanediol | 200 | ppm |
| (molecular weight = 6000): | | |

Perform an electroplating process by using the foregoing chip and pure copper as electrodes as mentioned above, with plating time being set for 90 seconds at current density of 2 ASD. Results indicate the forming of a surface-flat and void-free plated copper later respectively for all trenches with various line widths of 0.25 μm, 0.45 μm, and 2.7 μm.

### EXAMPLE 3

Take a chip routed with trenches as cathode and pure copper as anode; prepare a power supply of EG & G Potentiostat/Galvanostat model 263A. An electroplating composition is constituted as follows:

| | | |
|---|---|---|
| copper ion: | 17 | g/L |
| sulfuric acid: | 180 | g/L |
| cysteine: | 20 | ppm |
| polyethanediol | 200 | ppm |
| (molecular weight = 6000): | | |

Perform an electroplating process by using the foregoing chip and pure copper as electrodes as mentioned above, with plating time being set for 90 seconds at current density of 2 ASD. Results indicate the forming of a surface-flat and void-free plated copper later respectively for all trenches with various line widths of 0.25 μm, 0.45 μm, and 2.7 μm.

### EXAMPLE 4

Take a chip routed with trenches as cathode and pure copper as anode; prepare a power supply of EG & G Potentiostat/Galvanostat model 263A. An electroplating composition is constituted as follows.

| | | |
|---|---|---|
| copper ion: | 57 | g/L |
| sulfuric acid: | 18.4 | g/L |
| chloride ion: | 40 | ppm |
| glutathione: | 20 | ppm |
| polyethanediol | 200 | ppm |
| (molecular weight = 6000): | | |

Perform an electroplating process by using the foregoing chip and pure copper as electrodes as mentioned above, with plating time being set for 180 seconds at current density of 2 ASD. Results indicate the forming of a surface-flat and void-free plated copper later respectively for all trenches with various line widths of 0.25 μm, 0.45 μm, and 2.7 μm.

While the present invention has been described in conjunction with a specific best mode, it is to be understood that many alternatives, modifications, and variations will be apparent to those skilled in the art in light of the foregoing description. Accordingly, it is intended to embrace all such alternatives, modifications, and variations which fall within the spirit and scope of the included claims. All matters set forth herein or shown in the accompanying drawings are to be interpreted in an illustrative and non-limiting sense.

What is claimed is:

1. A copper electroplating composition for integrated circuit interconnection, comprising a copper salt, an inorganic acid containing same anion as the copper salt, a compound containing nitrogen and sulphurous, oxygen-containing polymer and chloride ions; wherein electroplating is performed at current density of 0.5 to 5 ASD and with copper serving as anode, so as to form a surface-flat and void-free plated copper layer.

2. The copper electroplating composition of claim 1, wherein line width used in the interconnection is smaller than 10 μm.

3. The copper electroplating composition of claim 1, wherein an aspect ratio used in the interconnection is from 0.05 to 10.

4. The copper electroplating composition of claim 1, wherein the copper salt is selected from a group consisting of copper sulfate, copper phosphate and copper nitrate.

5. The copper electroplating composition of claim 4, wherein the copper salt is copper sulfate.

6. The copper electroplating composition of claim 5, wherein content of copper sulfate ranges from 16 to 160 g/L.

7. The copper electroplating composition of claim 1, wherein the inorganic acid is selected from a group consisting of sulfuric acid, phosphoric acid and nitric acid.

8. The copper electroplating composition of claim 7, wherein the inorganic acid is sulfuric acid.

9. The copper electroplating composition of claim 8, wherein content of sulfuric acid ranges from 18 to 200 g/L.

10. The copper electroplating composition of claim 1, wherein the compound containing nitrogen and sulphurous is a sulphurous-containing amino acid compound.

11. The copper electroplating composition of claim 10, wherein the sulphurous-containing amino acid compound is selected from a group consisting of cysteine, percysteine, glutathione, and subsituents and salts thereof.

12. The copper electroplating composition of claim 10, wherein content of the sulphurous-containing amino acid compound ranges from 5 to 50 parts per million.

13. The copper electroplating composition of claim 1, wherein the oxygen-containing polymer includes polyethanediol, polypropanediol, and copolymer of ethanediol and propanediol.

14. The copper electroplating composition of claim 13, wherein content of the oxygen-containing polymer ranges from 100 to 1000 parts per million.

15. The copper electroplating composition of claim 1, wherein content of the chloride ions ranges from 1 to 100 parts per million.

16. The copper electroplating composition of claim 1, wherein the anode includes pure copper and phosphorous-containing copper.
